(19) United States
(12) Patent Application Publication
(10) Pub. No.: US 2020/0127017 A1
(43) Pub. Date: Apr. 23, 2020

(54) DISPLAY SUBSTRATE, DISPLAY PANEL, AND DISPLAY DEVICE

(71) Applicant: HKC Corporation Limited, Shenzhen (CN)

(72) Inventor: Peixin Lin, Shenzhen (CN)

(21) Appl. No.: 16/446,613

(22) Filed: Jun. 19, 2019

Related U.S. Application Data
(63) Continuation of application No. PCT/CN2018/119050, filed on Dec. 4, 2018.

(30) Foreign Application Priority Data
Oct. 23, 2018 (CN) 201821722173.4

(51) Int. Cl. H01L 27/12

(52) U.S. Cl. CPC H01L 27/1244; H01L 21/76894

(57) ABSTRACT

Disclosed a display substrate, a display panel, and a display device. The display substrate includes: a substrate body having a display area and a non-display area; a driving signal line disposed in the non-display area; and a controlling signal line disposed in the non-display area, the driving signal line and the controlling signal line are disposed to form an intersecting area, and the driving signal line is provided with a first repairing hole in the intersecting area to divide the intersecting area of the driving signal line into a first intersecting segment and a second intersecting segment.

### CROSS-REFERENCE TO RELATED APPLICATIONS

The present application is a Continuation Application of International Application No. PCT/CN2018/119050, filed on Dec. 4, 2018, which claims the benefit of China Patent Application No. 201821722173.4, filed Oct. 23, 2018 with the State Intellectual Property Office and entitled “Display Substrate, Display Panel, and Display Device”, the entirety of which is hereby incorporated herein by reference.

### TECHNICAL FIELD

The present disclosure relates to the field of display device manufacturing technology, and more particularly relates to a display substrate, a display panel, and a display device.

### BACKGROUND

In the production process of the display screen with Gate Driver on Array (GOA) driving system, a driving unit and a controlling unit are usually provided in the non-display area of the display substrate. The driving unit and the controlling unit are electrically connected with each other by a plurality of crossing signal lines. If conductive particles fall into the intersecting area of the two signal lines, may result in the two signal lines being short-circuited across the layer, and further result in an abnormal display on the finished display. When the wires in different structural layers are short-circuited in the intersecting area, it is difficult to repair or even impossible to repair. For the products with such defects, the products are usually directly disposed, which results in waste of resources and increase of the production costs.

### SUMMARY

The main purpose of this application is to propose a display substrate aiming to solve the technical problem of reducing the production cost of the display.

To achieve the above object, the present application provides a display substrate, including:

a substrate body, having a display area and a non-display area;

a driving signal line, defined in the non-display area; and

a controlling signal line, defined in the non-display area, the driving signal line and the controlling signal line being defined crosswise to form an intersecting area, and the driving signal line being provided with a first repairing hole in the intersecting area to divide the intersecting area of the driving signal line into a first intersecting segment and a second intersecting segment.

Optionally, the first repairing hole extends along a width direction of the controlling signal line.

Optionally, the driving signal line and the controlling signal line are disposed perpendicularly to each other.

Optionally, the first repairing hole is arranged in a rectangle.

Optionally, the controlling signal line is provided with a second repairing hole in the intersecting, and the second repairing hole extends along a width direction of the driving signal line to separate the intersecting of the controlling signal line into the third cross segment and the fourth cross segment.

Optionally, the second repairing holes protrude from both side edges of the driving signal line along a width direction of the driving signal line.

Optionally, the width of the driving signal line is smaller than the width of the controlling signal line.

Optionally, the controlling signal line further defines a third repairing hole in the third intersecting segment or the fourth intersecting segment, the third repairing hole extending along a width direction of the driving signal line to The third intersecting segment or the fourth intersecting segment is divided into a fifth intersecting segment and a sixth intersecting segment.

Optionally, the third repairing hole is the same size as the second repairing hole.

Optionally, the fourth intersecting segment, the fifth intersecting segment, and the sixth intersecting segment are the same size.

Optionally, the fourth intersecting segment, the fifth intersecting segment, and the sixth intersecting segment all have a width of at least 5 microns.

Optionally, the number of the controlling signal lines is plural, a plurality of the controlling signal lines are spaced apart along the length direction of the driving signal line, and the plurality of the controlling signal line and the driving signal lines are defined crosswise to form a plurality of the intersecting areas, the driving signal lines are provided with the first repairing holes in each of the intersecting regions.

Optionally, the number of the driving signal lines is plural, a plurality of the driving signal lines are spaced apart along the length direction of the controlling signal line, and the plurality of the controlling signal line and the driving signal lines are defined crosswise to form a plurality of the intersecting areas s, the driving signal lines are provided with the first repairing holes in each of the intersecting regions, and the controlling signal line is provided with the second repairing holes in each of the intersecting regions.

Optionally, the first cross segment and the second cross segment have a width of at least 5 microns.

Alternatively, the drive signal line has a width of 20 microns.

Optionally, the width of the controlling signal line is 60 microns.

The present application also provides a display panel comprising a display substrate, the display substrate comprising: a substrate body having a display area and a non-display area; a driving signal line disposed in the non-display area; a controlling signal line, Provided in the non-display area, the driving signal line and the controlling signal line are disposed to form an intersecting, and the driving signal line is provided with a first repairing hole in the intersecting to drive the driving signal line The intersecting area is divided into a first intersecting segment and a second intersecting segment.

Optionally, the display panel further includes a scan driving unit disposed in the non-display area, and one end of the driving signal line is electrically connected to the scan driving unit.

Optionally, the display panel further includes a data driving unit disposed in the non-display area, and one end of the controlling signal line is electrically connected to the data driving unit.

The present application also provides a display device, including a display panel, the display panel includes a display substrate, the display substrate includes: a substrate body having a display area and a non-display area; and a driving signal line disposed on the non-display a display area; a controlling signal line disposed in the non-display area, the driving signal line and the controlling signal line are disposed to form an intersecting area, and the driving signal line is provided with a first repairing hole in the intersecting area, separating the intersecting of the driving signal lines into a first intersecting segment and a second intersecting segment.

The present application shows that the substrate has a first repairing hole formed in the intersecting of the driving signal lines, and the first repairing hole divides the intersecting of the driving signal lines into the first intersecting segment and the second intersecting segment in the width direction of the driving signal line. Thereby, the intersecting area of the driving signal line and the controlling signal line is reduced, thereby reducing the risk that the foreign matter falls in the intersecting area and causing the controlling signal line and the driving signal line to be short-circuited, so as to reduce the defect rate of the display screen; if the foreign object falls on the first For the intersecting segment or the second intersecting segment, it is only necessary to cut the parts on both sides of the first intersecting segment or the second intersecting segment to disconnect the foreign object from the driving signal line. At this time, the driving signal line can be the electrical connection is made by the uncut cross segment, thereby effectively repairing the position where the controlling signal line and the driving signal line are short-circuited, thereby reducing the defect rate of the display substrate, thereby reducing the overall production cost of the display screen.

### BRIEF DESCRIPTION OF THE ACCOMPANYING DRAWINGS

In order to more clearly illustrate the embodiments of the present application or the technical solutions in the exemplary technology, the drawings to be used in the embodiments or the description of the prior art will be briefly described below. Obviously, the drawings in the following description are only embodiments of the present application, and other drawings can be obtained according to the structures shown in the drawings without any creative work for those skilled in the art.

FIG. 1 is a schematic structural diagram of a display substrate of an embodiment in accordance with this disclosure;

FIG. 2 is a partial enlarged view of a portion A in FIG. 1;

FIG. 3 is a schematic structural diagram of a display panel of an embodiment in accordance with this disclosure;

FIG. 4 is a schematic diagram of a display device of an embodiment in accordance with this disclosure.

### DESCRIPTION OF THE REFERENCE NUMERALS

| Label | name | Label | name | Label | name |
|---|---|---|---|---|---|
| 10 | Substrate body | 11 | Display area | 12 | Non-display area |
| 20 | Drive signal line | 30 | Controlling signal | 21 | First repairing hole |
| | | | line | | |
| 22 | First intersecting | 23 | Second intersecting | 31 | Second repairing |
| | | | | | hole |
| 32 | Third intersecting | 33 | Fourth intersecting | 34 | Third repairing hole |
| 35 | Fifth cross segment | 36 | Sixth intersecting | 100 | Display panel |
| 200 | Display device | | | | |

Various implementations, functional features, and advantages of this disclosure will now be described in further detail in connection with some illustrative embodiments and the accompanying drawings.

### DETAILED DESCRIPTION OF ILLUSTRATIVE EMBODIMENTS

The technical schemes in the embodiments of the present application are clearly and completely described in the following embodiments with drawings of the present application. It is obvious that the described embodiments are a part, not all, of the embodiments of the present application. All other embodiments obtained by an ordinary skilled person in the art based on the embodiments of the present application without departing from the inventive scope are fall into the scope of the present application.

It should be noted that all directional indicators (such as “up” “down” “left” “right” “front” or “rear”) as merely used to illustrate the relative positions and movements or the like of various components or parts under a specific posture (as depicted in the drawings), and if the specific posture change, these directional indicators will change accordingly.

In addition, the descriptions of “first”, “second” and the like in this application are used for descriptive purposes only and are not to be construed as indicating or implying a relative importance or implicitly indicating the number of technical features. Thus, features defined by “first” and “second” may include at least one of the features either explicitly or implicitly. In addition, the meaning of “and/or” appearing throughout the text includes three parallel schemes, “A and/or B as an example”, including the A scheme, or the B scheme, or the scheme in which both A and B are simultaneously satisfied. In addition, the technical solutions between the various embodiments may be combined with each other, but must be based on the realization of those skilled in the art, and when the combination of the technical solutions is contradictory or impossible to implement, it should be considered that the combination of the technical solutions does not exist. Nor is it within the scope of protection required by this application.

The application proposes a display substrate for using in a display screen.

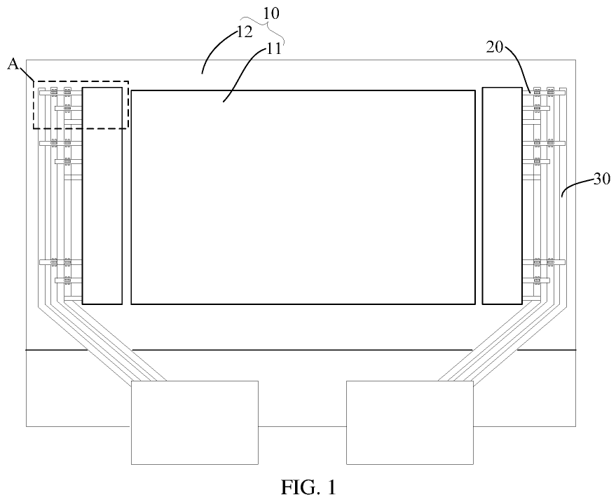

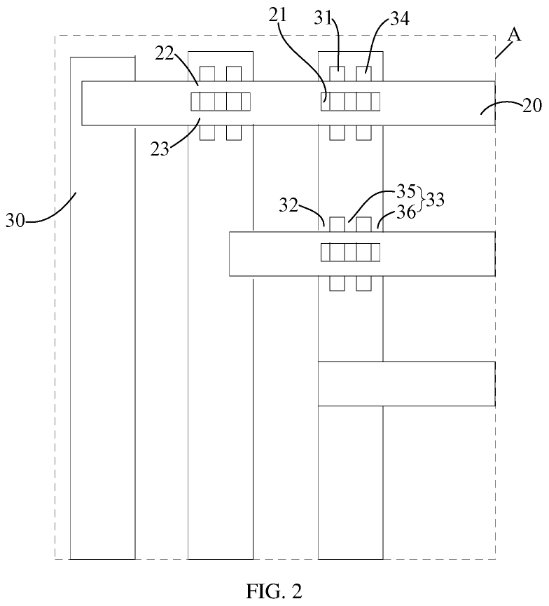

In the embodiment of the present application, as shown in FIG. 1 and FIG. 2, the display substrate includes:

The substrate body 10 has a display area 11 and a non-display area 12;

The driving signal line 20, disposed in the non-display area 12;

The controlling signal line 30 is disposed in the non-display area 12, and the driving signal line 20 is disposed at an intersecting with the controlling signal line 30 to form an intersecting area, and the driving signal line 20 is provided with a first repair in the intersecting area. The hole 21 is formed to divide the intersecting of the driving signal line 20 into the first intersecting segment 22 and the second intersecting segment 23.

In this embodiment, the display screen adopts the GOA technology to realize the driving display mode of the progressive scanning, and the driving technology has the advantages of reducing the production cost and realizing the narrow frame design of the panel. In the process of preparing the display screen by using the GOA technology, a scan driving unit and a data driving unit are disposed in the non-display area 12 of the display screen, one end of the driving signal line 20 is electrically connected to the scanning driving unit, and the other end is electrically connected to the data driving unit; One end of the controlling signal line 30 is electrically connected to the data driving unit, and the body is electrically connected to the driving signal line 20. It should be noted that the number of the driving signal line 20 and the controlling signal line 30 is plural, the plurality of driving signal lines 20 are disposed to intersect with the plurality of controlling signal lines 30, and one driving signal line 20 is only electrically connected to one controlling signal line 30, that is, before each of the driving signal lines 20 is electrically connected to the corresponding controlling signal line 30 at its end, the driving signal line 20 is crossed and insulated from the other controlling signal lines 30 to realize the stable transmission of data signals between scanning driving unit and the data driving unit. The driving signal line 20 and the controlling signal line 30 are performed in the non-display area 12 of the substrate body 10 in the preparation process of the display substrate.

The position where the driving signal line 20 intersects with the controlling signal line 30, that is, the position where the projection overlaps forms an intersecting region, and the first repairing hole 21 is opened at the intersecting region of the driving signal line 20, and dividing the intersection area into the first intersecting segment 22 and the second intersecting segment 23 along the width direction of the driving signal line 20, the inner edges of the first intersecting segment 22 and the second intersecting segment 23 are the edge of the first repairing hole 21, and the shape of the first repairing hole 21 may be a circle, a rectangle, a waist, or the like.

When the conductive foreign matter falls into the intersecting of the driving signal line 20, causing the driving signal line 20 and the controlling signal line 30 to be electrically short-circuited at the position, the display effect of the display screen may be abnormal, and the position of the short circuit may be determined by the detecting device. If the conductive foreign matter falls on the first intersecting segment 22, the portions on both sides of the conductive foreign matter on the first intersecting segment 22 may be cut, such as by a laser cutting process, to disconnect the conductive foreign matter from the overall circuit, thereby realizing the short circuit problem repair of the position realizing, at which time the drive signal line 20 remains electrically connected through the second cross segment 23.

The present application shows that the substrate has a first repairing hole 21 formed in the intersecting of the driving signal line 20, and the first repairing hole 21 divides the intersecting area of the driving signal line 20 into a first intersecting segment 22 and a second intersecting segment 23 in the width direction of the driving signal line 20, thereby reducing the intersecting area of the driving signal line 20 and the controlling signal line 30, thereby reducing the risk that foreign matter falling in the intersecting area that causes the controlling signal line 30 and the driving signal line 20 to be short-circuited, thereby reducing the defect rate of the display screen. If the foreign matter falls on the first intersecting segment 22 or the second intersecting segment 23, it is only necessary to cut the portions on both sides of the foreign object on the first intersecting segment 22 or the second intersecting segment 23, to drive the foreign matter part to be disconnected from the driving signal line 20. At this time, the driving signal line 20 can be electrically connected through the uncut cross segment, thereby effectively repairing the short-circuited position of the controlling signal line 30 and the driving signal line 20. The defect rate of the display substrate is lowered, thereby reducing the production cost of the entire display screen.

Further, as shown in FIG. 2, the first repairing hole 21 extends in the width direction of the controlling signal line 30. In the present embodiment, the driving signal line 20 and the controlling signal line 30 are disposed perpendicularly to each other, and the first repairing card hole extends in the width direction of the controlling signal line 30, that is, extends along the length direction of the driving signal line 20. It should be noted that the width direction of the controlling signal line 30 is the extending direction of the short side of the projection of the controlling signal line 30 on the substrate body 10; the length direction of the driving signal line 20 is the extending direction of the long side of the projection of the driving signal line 20 on the substrate body 10. The first repairing hole 21 may be arranged in a rectangular shape as a whole, and the first repairing hole 21 extends along the width direction of the controlling signal line 30, and the size of the first intersecting segment 22 and the second intersecting segment 23 may be increased in the direction, thereby the cuttable area of the first intersecting segments 22 and the second intersecting segment 23 can be increased, makes the repairing process of the short-circuited position more simple and convenient.

Further, as shown in FIG. 2, the controlling signal line 30 is provided with a second repairing hole 31 at the intersecting area, and the second repairing hole 31 extends along the width direction of the driving signal line 20, to divide the intersecting area of the controlling signal line 30 into a third intersecting segment 32 and a fourth intersecting segment 33. In the present embodiment, the roles of the third intersecting segment 32 and the fourth intersecting segment 33 are the same as those of the first intersecting segment 22 and the second intersecting segment 23. The portion where the first repairing hole 21 intersects the second repairing hole 31 can reduce the area of the intersecting region, thereby reducing the risk of the conductive foreign matter falling in the intersecting region causing a short circuit. In addition, if both the first intersecting 22 and the second intersecting 23 fall into the foreign object, in order to maintain at least one intersecting connection, the short position can be repaired by cutting the third intersecting 32 or the third intersecting 32 of the corresponding position. Thereby, the stability of the operation of the driving signal line 20 and the controlling signal line 30 is ensured.

Further, as shown in FIG. 2, the second repairing holes 31 protrude from both side edges of the drive signal line 20 in the width direction of the drive signal line 20. In this embodiment, the edge of the second repairing hole 31 protrudes from both side edges of the driving signal line 20, which can further reduce the area of the intersecting area, thereby reducing the risk of the conductive foreign matter falling into the short circuit; in addition, the edge of the second repairing hole 31 protrudes from both side edges of the drive signal line 20, that is, the third intersecting segment 32 and the fourth intersecting segment 33 protrude from both side edges of the driving signal line 20, further increasing the cuttable area of the third intersecting segment 32 and the fourth intersecting segment 33 makes the repairing process of the short-circuited position more simple and convenient. In practical applications, since the width of the driving signal line 20 is smaller than the width of the controlling signal line 30, the first repairing hole 21 may not protrude from the edge of the controlling signal line 30 to ensure the first intersecting segment 22 and the second crossover. The connection strength of the segment 23 ensures the stability of the operation of the controlling signal line 30.

Further, as shown in FIG. 2, the controlling signal line 30 is further provided with a third repairing hole 34 at the third intersecting segment 32 or the fourth intersecting segment 33, and the third repairing hole 34 extends in the width direction of the driving signal line 20 to divide the third intersecting segment 32 or the fourth intersecting segment 33 into a fifth intersecting segment 35 and a sixth intersecting segment 36. In this embodiment, the third repairing hole 34 is opened in the third intersecting segment 32, and the third repairing hole 34 and the second repairing hole 31 are the same size. The fourth intersecting segment 33, the fifth intersecting segment 35 and the third The dimensions of the six intersecting segments 36 are also set to be the same to equalize the joint strength and the cuttable area of each intersecting segment. The third repairing hole 34 can further reduce the area of the intersecting area, and at the same time, it is more convenient to cut the position of the conductive foreign matter, so that the repairing of the short-circuited position is more convenient.

Further, the width of the first intersecting segment 22 and the second intersecting segment 23 are at least 5 microns. In the present embodiment, the width of the driving signal line 20 can be 20 microns, the width of the controlling signal line 30 can be 60 microns. The width of the fourth intersecting segment 33, the fifth intersecting segment 35, and the sixth intersecting segment 36 can be at least 5 microns. The width of each intersecting segment are set to at least 5 microns, which enables each intersecting segment to have sufficient connection strength, and at the same time, can effectively reduce the area of the intersecting area, that is, while ensuring stable operation of the driving signal line 20 and the controlling signal line 30, at the same time reduce the risk of short-circuiting of conductive foreign objects in the intersection, and it is more convenient to cut the position of the conductive foreign matter, so that the repair of the short circuit position is more convenient.

Further, as shown in FIG. 1 and FIG. 2, the number of the controlling signal lines 30 is plural, and the plurality of the controlling signal lines 30 are spaced apart along the length direction of the driving signal line 20, and the plurality of driving signal lines 20 are disposed to intersect with the controlling signal line 30 to form a plurality of the intersecting areas, and the driving signal line 20 is provided with the first repairing holes 21 in each of the intersecting areas.

The number of the driving signal lines 20 is plural, and the plurality of the driving signal lines 20 are spaced apart along the length direction of the controlling signal line 30, and a plurality of the driving signal lines 20 are disposed to intersect with the control signal line 30 to form a plurality of the intersection regions, the driving signal line 20 is provided with the first repairing holes 21 in each of the intersecting regions, and the controlling signal line 30 is provided with the second repairing hole 31 in each of the intersections.

In the present embodiment, a plurality of driving signal lines 20 are disposed across the plurality of controlling signal lines 30, and the first repairing hole 21 are formed in the respective intersecting areas of the driving signal lines 20, and a second repairing hole 31 and a third repairing hole 34 are opened in each intersecting area of the controlling signal line 30, thereby dividing each intersection of the two signal lines into corresponding intersecting segments, for conveniently repairing the position where the conductive foreign matter may cause a short circuit, thereby improving the convenience of repairing the entire display substrate, thereby reducing the production cost of the display substrate.

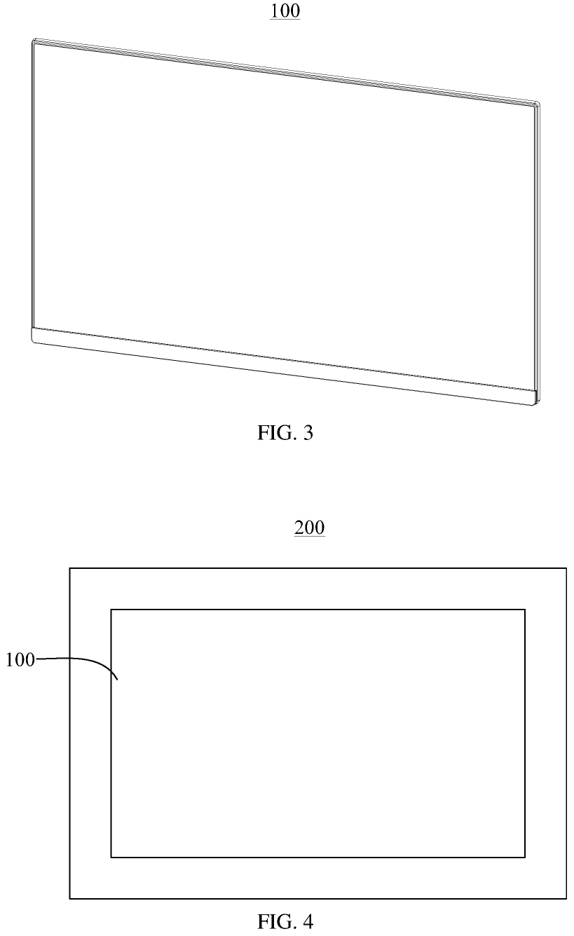

As shown in FIG. 3, the present application further provides a display panel 100 including a display substrate. The specific structure of the display substrate refers to the above embodiments, and the display panel 100 adopts all the technical solutions of all the above embodiments. Therefore, at least the technical effects brought about by the technical solutions of the foregoing embodiments are not repeatedly described herein.

As shown in FIG. 4, the present application further provides a display device 200 including a display panel 100. The specific structure of the display panel 100 refers to the above embodiment, and the display device 200 adopts all the above embodiments. The technical solution, therefore, has at least the technical effects brought about by the technical solutions of the above embodiments, and will not be further described herein.

The above is only the preferred embodiment of the present application and is not therefore limiting the scope of the patent of the present application. The equivalent structure or equivalent process changes made in the application specification and drawings, or directly or indirectly applied in other related technical fields, are similarly included in the patent protection scope of this application.

What is claimed is:

1. A display substrate, comprising:
a substrate body, having a display area and a non-display area;
a driving signal line, defined in the non-display area; and
a controlling signal line, defined in the non-display area, the driving signal line and the controlling signal line being defined crosswise to form an intersecting area, and the driving signal line being provided with a first repairing hole in the intersecting area to divide the intersecting area of the driving signal line into a first intersecting segment and a second intersecting segment.

2. The display substrate of claim 1, wherein the first repairing hole extends along the width direction of the controlling signal line.

3. The display substrate of claim 2, wherein the driving signal line and the controlling signal line are disposed perpendicularly to each other.

4. The display substrate of claim 2, wherein the first repairing hole is rectangular.

5. The display substrate of claim 1, wherein the controlling signal line is provided with a second repairing hole in the intersecting area, and the second repairing hole extends along the width direction of the driving signal line to divide the intersecting area of the controlling signal line into a third intersecting segment and a fourth intersecting segment.

6. The display substrate of claim 5, wherein the second repairing hole protrudes from both edges of the driving signal along the width direction of the driving signal line.

7. The display substrate of claim 6, wherein a width of the driving signal line is smaller than a width of the controlling signal line.

8. The display substrate of claim 5, wherein the controlling signal line is further provided with a third repairing hole in the third intersecting segment or the fourth intersecting segment, the third repairing hole extends along the width direction of the driving signal line to divide the third intersecting segment or the fourth intersecting segment into a fifth intersecting segment and a sixth intersecting segment.

9. The display substrate of claim 8, wherein the third repairing hole is the same size as the second repairing hole.

10. The display substrate of claim 8, wherein the fourth intersecting segment, the fifth intersecting segment, and the sixth intersecting segment are the same size.

11. The display substrate of claim 8, wherein the fourth intersecting segment, the fifth intersecting segment, and the sixth intersecting segment all have a width of at least 5 microns.

12. The display substrate of claim 1, wherein the number of the controlling signal lines is plural, and the plurality of the controlling signal lines are spaced apart along a length direction of the driving signal line, and the plurality of the controlling signal line and the driving signal lines are defined crosswise to form a plurality of the intersecting areas, and the driving signal lines are provided with the first repairing hole in each intersecting area.

13. The display substrate of claim 5, wherein the number of the controlling signal lines is plural, and the plurality of the controlling signal lines are spaced apart along a length direction of the driving signal line, and the plurality of the controlling signal line and the driving signal lines are defined crosswise to form a plurality of the intersecting areas, the driving signal lines are provided with the first repairing hole in each intersecting area, and the controlling signal lines are provided with the second repairing hole in each intersecting area.

14. The display substrate of claim 1, wherein the first intersecting segment and the second intersecting segment both have a width of at least 5 microns.

15. The display substrate of claim 14, wherein the driving signal line has a width of 20 microns.

16. The display substrate of claim 14, wherein the controlling signal line has a width of 60 microns.

17. A display panel, wherein the display panel comprises a display substrate, and the display substrate comprises:
a substrate body, having a display area and a non-display area;
a driving signal line, defined in the non-display area; and
a controlling signal line, defined in the non-display area, the driving signal line and the controlling signal line being defined crosswise to form an intersecting area, and the driving signal line being provided with a first repairing hole in the intersecting area to divide the intersecting area of the driving signal line into a first intersecting segment and a second intersecting segment.

18. The display panel of claim 17, wherein the display panel further comprises a scan driving unit disposed in the non-display area, and one end of the driving signal line is electrically connected to the scan driving unit.

19. The display panel of claim 18, wherein the display panel further comprises a data driving unit disposed in the non-display area, and one end of the controlling signal line is electrically connected to the data driving unit.

20. A display device, wherein the display device comprises a display panel, the display panel comprises a display substrate, and the display substrate comprises:
a substrate body, having a display area and a non-display area;
a driving signal line, defined in the non-display area; and
a controlling signal line, defined in the non-display area, the driving signal line and the controlling signal line being defined crosswise to form an intersecting area, and the driving signal line being provided with a first repairing hole in the intersecting area to divide the intersecting area of the driving signal line into a first intersecting segment and a second intersecting segment.
